(19) United States
(12) Patent Application Publication
(10) Pub. No.: US 2014/0032994 A1
(43) Pub. Date: Jan. 30, 2014

(54) TRANSMISSION APPARATUS

(71) Applicant: FUJITSU LIMITED, Kawasaki-shi (JP)

(72) Inventor: Jyunichi ISHIWATARI, Kawasaki (JP)

(73) Assignee: FUJITSU LIMITED, Kawasaki-shi (JP)

(21) Appl. No.: 13/893,716

(22) Filed: May 14, 2013

(30) Foreign Application Priority Data
Jul. 24, 2012 (JP) 2012-163578

(51) Int. Cl. H03M 13/05

(52) U.S. Cl. CPC H03M 13/05
USPC 714/776

(57) ABSTRACT

An transmission apparatus includes: a switching signal generation circuit configured to generate a switching signal in accordance with an error of a received signal; a switching circuit configured to perform reception switching in which a line through which the transmission apparatus receives a signal is switched from a working line to a protection line in accordance with the switching signal; an error correction circuit configured to correct the error of the received signal; and a switching signal control circuit configured to control input of the switching signal to the switching circuit in accordance with whether or not the error correction circuit corrects the error of the received signal.

### CROSS-REFERENCE TO RELATED APPLICATION

This application is based upon and claims the benefit of priority from the prior Japanese Patent Application No. 2012-163578 filed on Jul. 24, 2012, the entire contents of which are incorporated herein by reference.

### FIELD

The embodiments discussed herein are related to a transmission apparatus including a control function that switches between transmission paths in the case of a transmission path failure in a network in which a plurality of transmission apparatuses are connected to each other.

### BACKGROUND

A technique is known in which, when a failure occurs in a network which is formed such that a plurality of transmission apparatuses are connected to each other with a plurality of transmission paths, the portion in which the failure occurred is bypassed by using a protection line and the failure is thereby dealt with. An example of the technique is a ring protection, such as a unidirectional path switched ring (UPSR) or a bidirectional line switched ring (BLSR), in synchronous optical network/synchronous digital hierarchy (SONET/SDH).

A line switching scheme is known in which digital transmission apparatuses of a working system and a protection system are provided. The digital transmission apparatus of the protection system includes a station for radio transmission to which one or more relay transmission paths are connected with one working line and a protection transmission unit which is common to transmission systems. A transmission side of the station for radio transmission includes a working-protection switching unit that performs working-protection switching on the basis of an input switching signal. A reception side of the station for radio transmission includes a frame synchronization circuit by which frame synchronization of a signal string received from the transmission side of the station for radio transmission is achieved, and an error detection circuit that detects a bit error rate on the basis of a frame pulse from the frame synchronization circuit. The reception side of the station for radio transmission further includes a receiving end switching circuit that performs working-protection switching on the basis of the switching signal.

Related art is disclosed in Japanese Laid-open Patent Publication No. 05-291982.

### SUMMARY

According to an aspect of the invention, an transmission apparatus includes: a switching signal generation circuit configured to generate a switching signal in accordance with an error of a received signal; a switching circuit configured to perform reception switching in which a line through which the transmission apparatus receives a signal is switched from a working line to a protection line in accordance with the switching signal; an error correction circuit configured to correct the error of the received signal; and a switching signal control circuit configured to control input of the switching signal to the switching circuit in accordance with whether or not the error correction circuit corrects the error of the received signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B each illustrate a BLSR;

FIG. 2 illustrates a hardware configuration according to a first embodiment of a transmission apparatus;

FIG. 3 illustrates BER ranges of a received signal within which error detection circuits are used;

FIG. 4 illustrates an example of the configuration of a switching signal control circuit illustrated in FIG. 2;

FIG. 5 illustrates a first example of a logic table of selection signals, error detection signals, and a switching signal;

FIG. 6 illustrates a second example of a logic table of selection signals, error detection signals, and a switching signal;

FIG. 7 illustrates a hardware configuration according to a second embodiment of the transmission apparatus;

FIGS. 8A and 8B each illustrate an example of the configuration of a switching signal control circuit illustrated in FIG. 7;

FIG. 9 illustrates a third example of a logic table of selection signals, error detection signals, a failure detection signal, and a switching signal;

FIGS. 10A to 10C each illustrate the operation performed by a failure detection circuit;

FIG. 11 illustrates error detection time periods; and

FIG. 12 illustrates cancellation time periods for error detection signals.

### DESCRIPTION OF EMBODIMENTS

Instantaneous line disconnection due to perform reception switching in which a line through which a transmission apparatus receives a signal is switched from a working line to a protection line occurs. Because line disconnection causes a frame loss, it is desirable that unnecessary switching between transmission paths be decreased. The transmission apparatus will be described below that is capable of reducing the occurrence of unnecessary switching between transmission paths in a network in which switching between transmission paths is performed when a failure occurs.

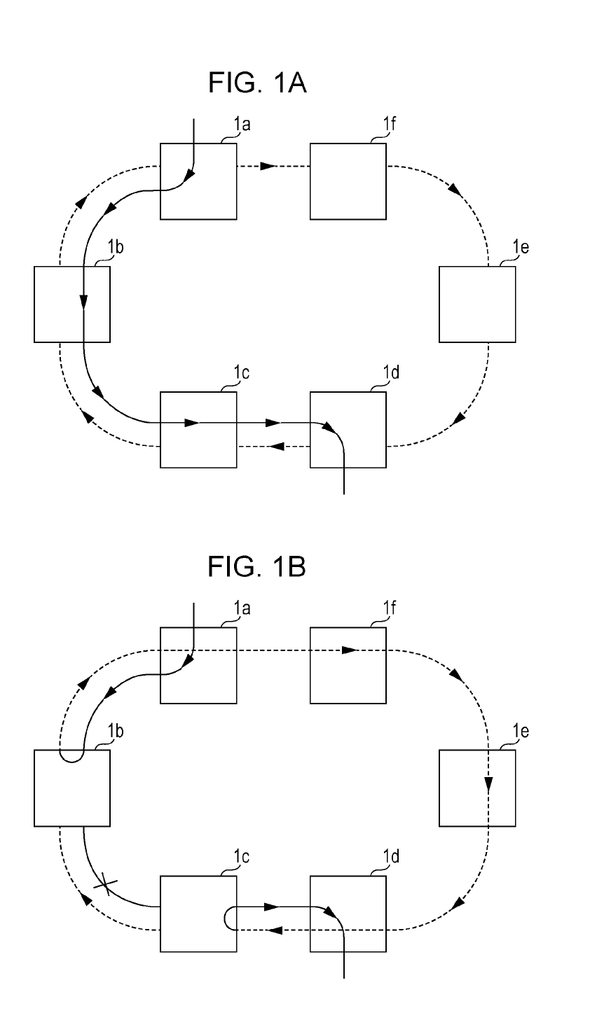

Desirable embodiments will be described below with reference to the accompanying drawings. Before description of a transmission apparatus according to the embodiments, an example of a transmission scheme will be described to which a switching operation of switching between transmission paths performed by the transmission apparatus according to the embodiments is applicable. FIGS. 1A and 1B each illustrate a BLSR to which the transmission apparatus according to the embodiments is applicable.

A ring network is formed of transmission apparatuses 1a, 1b, 1c, 1d, 1e, and 1f. A solid line in FIG. 1A denotes a working line that connects between the transmission apparatus 1a and the transmission apparatus 1d. The working line runs through the transmission apparatuses 1a, 1b, 1c, and 1d. A dotted line in FIG. 1A denotes a protection line.

FIG. 1B illustrates a state in which a failure occurred in the working line between the transmission apparatus 1b and the transmission apparatus 1c is bypassed by using the protection line. The transmission apparatus 1b performs transmission switching and the line through which a signal is transmitted is switched from the working line to the protection line. The signal is transmitted through the protection line, which runs through the transmission apparatuses 1a, 1f, 1e, and 1d, and up to the transmission apparatus 1c. The transmission apparatus 1c performs reception switching and the line through which the signal is transmitted is switched from the protection line to the working line. Subsequently, the signal is transmitted through the working line and up to the transmission apparatus 1d.

A method of switching between transmission paths and a transmission apparatus will be described below taking, as an example, reception switching performed by the foregoing transmission apparatus 1c. Note that it is not intended by the example that the method of switching between transmission paths and the transmission apparatus described herein be limited to a BLSR or a transmission apparatus that performs reception switching. As long as the method of switching between transmission paths and the transmission apparatus described herein are a method and a transmission apparatus that detect a failure in a transmission path and switch between transmission paths, the method of switching between transmission paths and the transmission apparatus described herein are also applicable to a transmission apparatus that performs another switching operation or another switching scheme. In the following description and the accompanying drawings, in some cases, the transmission apparatuses 1a to 1f are collectively referred to as “transmission apparatus 1”.

### First Embodiment

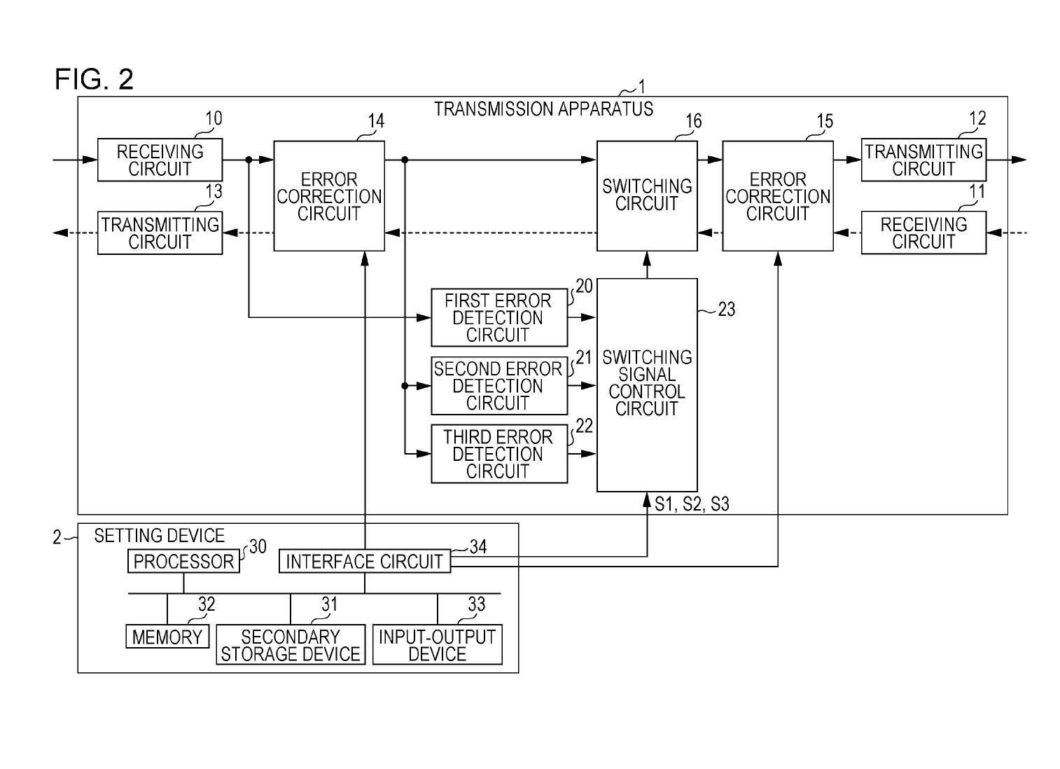

FIG. 2 illustrates a hardware configuration according to the first embodiment of a transmission apparatus 1. The transmission apparatus 1 includes receiving circuits 10 and 11, transmitting circuits 12 and 13, error correction circuits 14 and 15, and a switching circuit 16. The transmission apparatus 1 further includes a first error detection circuit 20, a second error detection circuit 21, a third error detection circuit 22, and a switching signal control circuit 23.

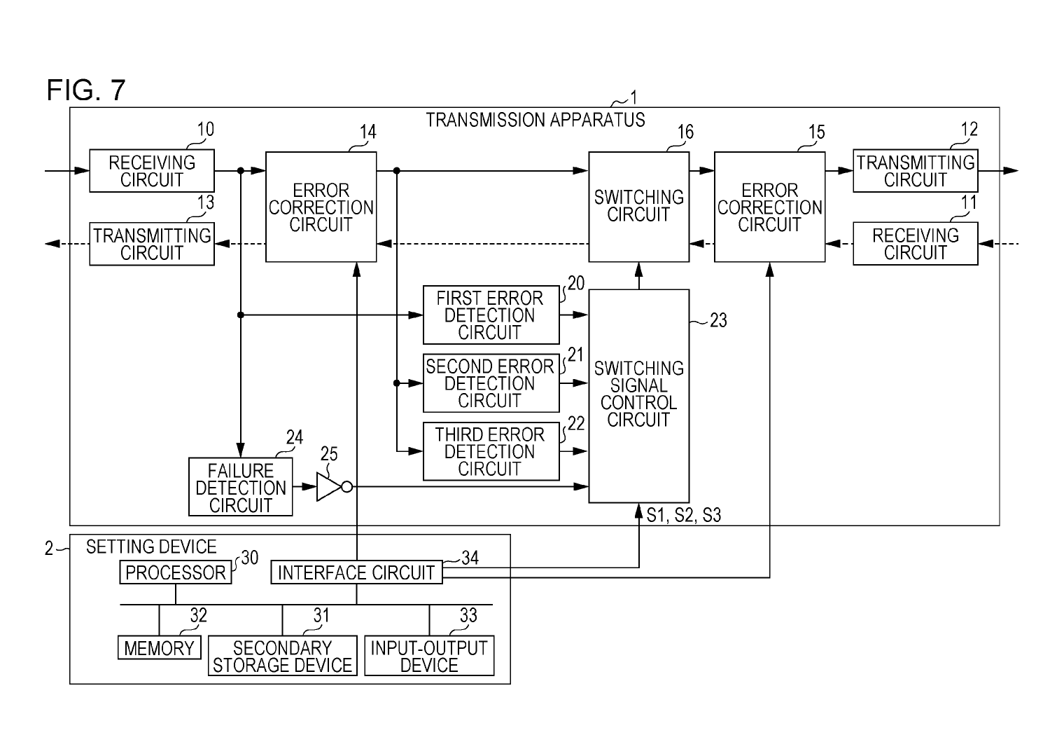

The hardware configuration illustrated in FIG. 2 is merely an example used to describe this embodiment. The transmission apparatus 1 described herein may employ any other hardware configuration as long as the hardware configuration is a configuration in which the operations described below are performed. FIG. 2 focuses on the configuration related to functions, in the transmission apparatus 1, which are described herein below. The transmission apparatus 1 may include components other than the components illustrated in FIG. 2. The same applies in the functional configuration drawing illustrated in FIG. 7.

The receiving circuits 10 and 11 respectively convert light signals received through a working line and a protection line into electric signals and input the electric signals to the error correction circuits 14 and 15. The error correction circuits 14 and 15 respectively perform, in accordance with a set signal specified by a setting device 2, error correction processes of the signals received from the receiving circuits 10 and 11.

The setting device 2 specifies an ON or OFF state of the error correction processes performed by the error correction circuits 14 and 15 and a mode of the error correction processes to be performed. The setting device 2 may be implemented by a computation device including a processor 30, a secondary storage device 31, a memory 32, an input-output device 33, and an interface circuit 34.

The error correction circuits 14 and 15 may perform error correction processes in a plurality of modes which are different in terms of error correction capability. Examples of the plurality of error correction capability modes include Reed-Solomon (255, 239) (RS (255, 239)) correction and advanced forward error correction (FEC) which has a higher error correction capability than RS (255, 239) correction. In another embodiment, the error correction circuits 14 and 15 may perform an error correction process other than RS (255, 239) correction and advanced FEC.

For example, RS (255, 239) correction has a capability to correct input signals having bit error rates (BERs) of 10⁻³, 10⁻⁴, and 10⁻⁵ to 10⁻⁹ so that the respective signals have BERs of about 9×10⁻⁵, about 9×10⁻¹⁴, and less than 10⁻¹⁶. On the other hand, advanced FEC is capable of correcting an input signal having a BER of about 8×10⁻³ so that the BER is less than 10⁻¹², and has a higher correction capability than RS (255, 239) correction.

In the following description, in some cases, among the error correction processes that the error correction circuits 14 and 15 are capable of performing, an error correction process having a relatively low correction capability and an error correction process having a relatively high correction capability are respectively referred to as a “first error correction process” and a “second error correction process”. In the following description, an example where the first error correction process and the second error correction process are respectively RS (255, 239) correction and advanced FEC is used.

A signal received by the receiving circuit 10 is input to the first error detection circuit 20, and the first error detection circuit 20 detects a failure in the working line through which the transmission apparatus 1 receives a signal. Examples of the failure in the working line detected by the first error detection circuit 20 include a loss of signal (LOS) and a loss of frame (LOF). An error detection signal of the first error detection circuit 20 is input to the switching signal control circuit 23.

A signal output from the error correction circuit 14 is input to the second error detection circuit 21, and the second error detection circuit 21 detects a signal failure (SF) error when the BER of the input signal is within the range of 10⁻³ to 10⁻⁵. Here, if the assumption is made that signals transmitted by the transmission apparatus 1 are an OC1 signal, an OC3 signal, an OC12 signal, and an OC48 signal, Telcordia recommendation GR-253-CORE, which is the specification standard of the transmission apparatus, defines a BER of less than 10⁻¹⁰ as a signal quality standard. As described above, RS (255, 239) correction corrects a signal having a BER of 10⁻³ so that the signal has a BER of about 9×10⁻⁵. Hence, within the BER range of 10⁻³ to 10⁻⁵, within which an error is detected by the second error detection circuit 21, a BER which is not corrected to such an extent that the signal quality standard is met is included even when RS (255, 239) correction is performed.

On the other hand, advanced FEC is capable of correcting an input signal having a BER of about 8×10⁻³ so that the BER is less than 10⁻¹². Hence, advanced FEC is capable of correcting even an input signal which RS (255, 239) correction is incapable of correcting to such an extent that the signal quality standard is met, so that the signal quality standard is met. In addition, a signal having a BER that is within the range of 10⁻³ to 10⁻⁵, within which an error is detected by the second error detection circuit 21, is corrected by advanced FEC so as to meet the signal quality standard.

A signal output from the error correction circuit 14 is input to the third error detection circuit 22, and the third error detection circuit 22 detects a signal degrade (SD) error when the BER of the input signal is within the range of 10⁻⁶ to 10⁻⁹. A signal having a BER that is within the range of 10⁻⁶ to 10⁻⁹ is corrected by either RS (255, 239) correction or advanced FEC so as to meet the signal quality standard.

Error detection signals of the second error detection circuit 21 and the third error detection circuit 22 are input to the switching signal control circuit 23. The first error detection circuit 20, the second error detection circuit 21, and the third error detection circuit 22 may output the error detection signals after a certain waiting time period has elapsed since errors were detected. For example, the certain waiting time period is the elapsed time period from when an error is detected to when an opposed transmission apparatus performs transmission switching. In another embodiment, a signal received by the receiving circuit 10 may be input to the second error detection circuit 21 and the third error detection circuit 22 without passing through the error correction circuit 14.

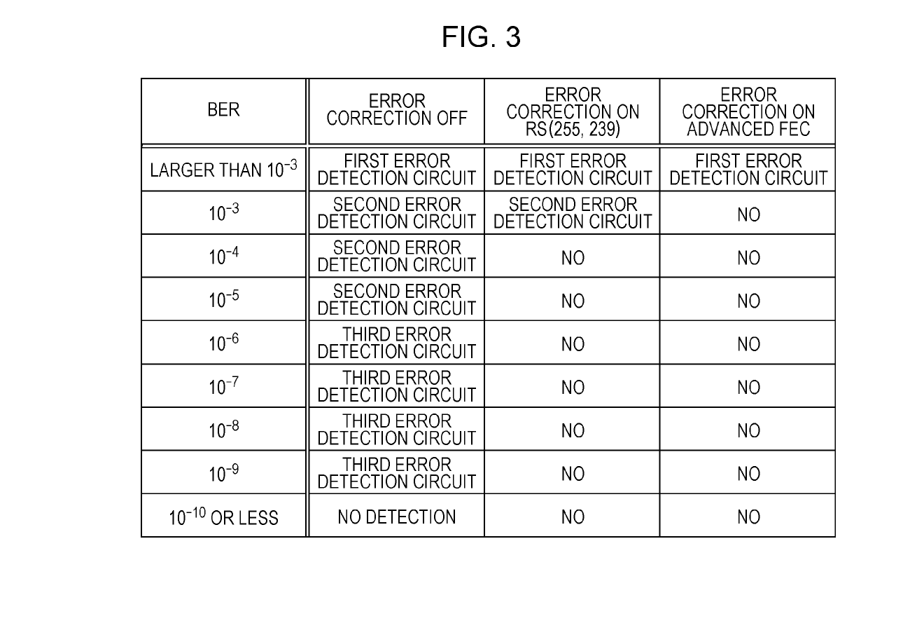

FIG. 3 illustrates BER ranges of a received signal within which the first error detection circuit 20, the second error detection circuit 21, and the third error detection circuit 22 are used for error detection. In the case where the error correction process performed by the error correction circuit 14 is in an OFF state, the first error detection circuit 20 is used for detection of an LOS error and an LOF error in which the BER of the received signal is larger than 10⁻³. The second error detection circuit 21 and the third error detection circuit 22 are respectively used for detection of an SF error in which the BER of the received signal is within the range of 10⁻³ to 10⁻⁵ and an SD error in which the BER of the received signal is within the range of 10⁻⁶ to 10⁻⁹.

In the case where the error correction process is in an ON state, when the performed error correction process is RS (255, 239) correction, the first error detection circuit 20 is used for detection of an LOS error and an LOF error in which the BER of the received signal is larger than 10⁻³. The second error detection circuit 21 is used for detection of an error of the received signal having such a BER (about 10⁻³) that even RS (255, 239) correction is incapable of correcting to such an extent that the signal quality standard is met. The signal having a BER that is within the range of 10⁻⁶ to 10⁻⁹, within which the third error detection circuit 22 detects an error, is corrected by RS (255, 239) correction to such an extent that the signal quality standard is met. Thus, the third error detection circuit 22 does not have to be used.

In the case where the error correction process is in an ON state, when the performed error correction process is advanced FEC, the first error detection circuit 20 is used for detection of an LOS error and an LOF error in which the BER of the received signal is larger than 10⁻³. The signal having a BER that is within the range of 10⁻³ to 10⁻⁹, within which the second error detection circuit 21 and the third error detection circuit 22 detect an error, is corrected by advanced FEC to such an extent that the signal quality standard is met. Thus, the second error detection circuit 21 and the third error detection circuit 22 do not have to be used.

The switching signal control circuit 23 generates, on the basis of error detection signals of the first error detection circuit 20, the second error detection circuit 21, and the third error detection circuit 22, a switching signal which causes reception switching to be performed by the transmission apparatus 1. When the switching circuit 16 receives the switching signal from the switching signal control circuit 23, the switching circuit 16 performs reception switching in which the line through which the transmission apparatus 1 receives a signal is switched from the working line to the protection line.

The setting device 2 inputs, to the switching signal control circuit 23, selection signals S1, S2, and S3 that indicate which of error detection signals of the first error detection circuit 20, the second error detection circuit 21, and the third error detection circuit 22 is selected in accordance with an ON or OFF setting and a mode setting of the error correction process performed by the error correction circuit 14. The switching signal control circuit 23 outputs an error detection signal, as the switching signal, selected by using the selection signals S1 to S3 from among the respective error detection signals of the first error detection circuit 20, the second error detection circuit 21, and the third error detection circuit 22.

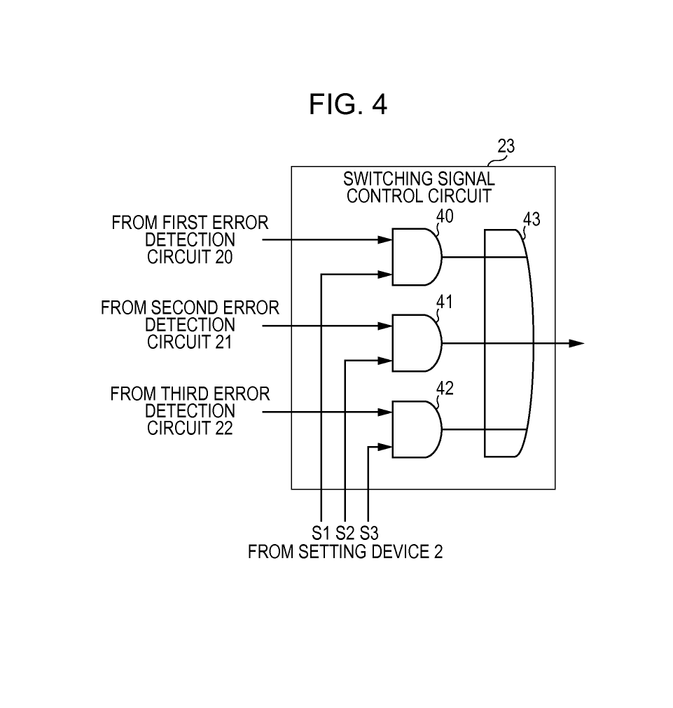

FIG. 4 illustrates an example of the configuration of the switching signal control circuit 23. The switching signal control circuit 23 includes AND circuits 40, 41, and 42, and an OR circuit 43. The AND circuit 40 outputs a logical product signal of the error detection signal of the first error detection circuit 20 and the selection signal S1. The AND circuit 41 outputs a logical product signal of the error detection signal of the second error detection circuit 21 and the selection signal S2. The AND circuit 42 outputs a logical product signal of the error detection signal of the third error detection circuit 22 and the selection signal S3. The OR circuit 43 outputs a logical sum signal of the outputs of the AND circuits 40, 41, and 42 to the switching circuit 16.

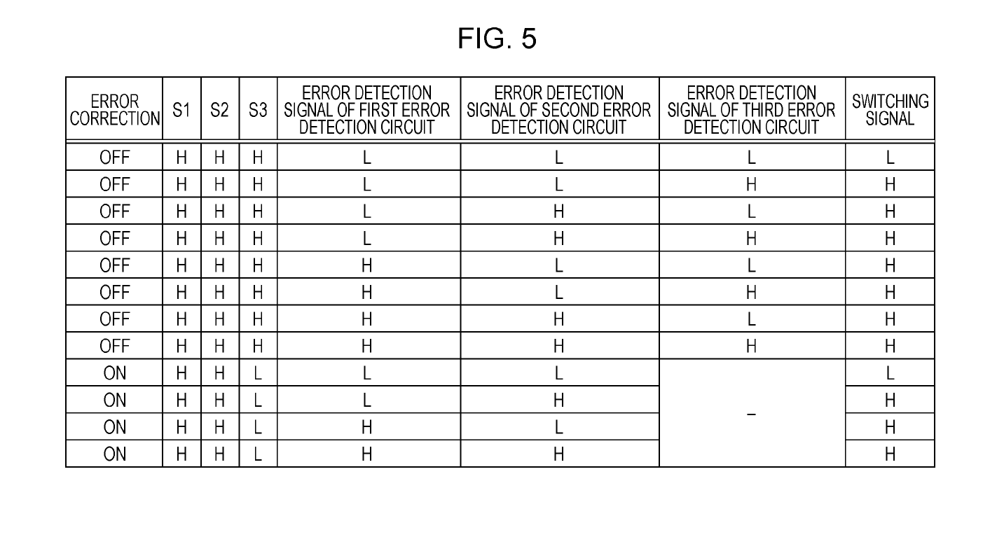

FIG. 5 is a logic table of selection signals S1 to S3, error detection signals, and a switching signal when RS (255, 239) correction is used. The values “H” and “L” of the selection signals S1 to S3 respectively denote a selection state and a non-selection state. The values “H” and “L” of the error detection signals of the first to third error detection circuits 20 to 22 respectively denote a state in which an error occurs and a state in which an error does not occur. The value “H” of the switching signal gives an instruction to switch between lines, and the value “L” of the switching signal gives an instruction not to switch between lines.

When RS (255, 239) correction is used, in the case where the error correction process is in an OFF state, the values of all the selection signals S1 to S3 are “H”. Thus, when any of the first error detection circuit 20, the second error detection circuit 21, and the third error detection circuit 22 detects an error, the value of the switching signal is “H”. In the case where the error correction process is in an ON state, the values of the selection signals S1 and S2 are “H” and the value of the selection signal S3 is “L”. Thus, the value of the switching signal is determined regardless of the error detection signal of the third error detection circuit 22. Hence, switching based on the error detection signal of the third error detection circuit 22 which is unnecessary when the error correction process performed by using RS (255, 239) correction is in an ON state is inhibited. As a result, the occurrence of unnecessary switching between transmission paths is reduced.

In the transmission apparatus 1, in the case where only RS (255, 239) correction is used as the error correction process, when the second error detection circuit 21 detects an error, the value of the switching signal is “H” regardless of an ON or OFF state of the error correction process. Accordingly, regardless of an ON or OFF state of the error correction process, the switching signal control circuit 23 may be configured so as to output the error detection signal of the second error detection circuit 21 as the switching signal. This configuration may simplify the configuration of the switching signal control circuit 23. For example, in the example of the switching signal control circuit 23 illustrated in FIG. 4, the AND circuit 41 may be omitted and the error detection signal from the second error detection circuit 21 may be input to the OR circuit 43.

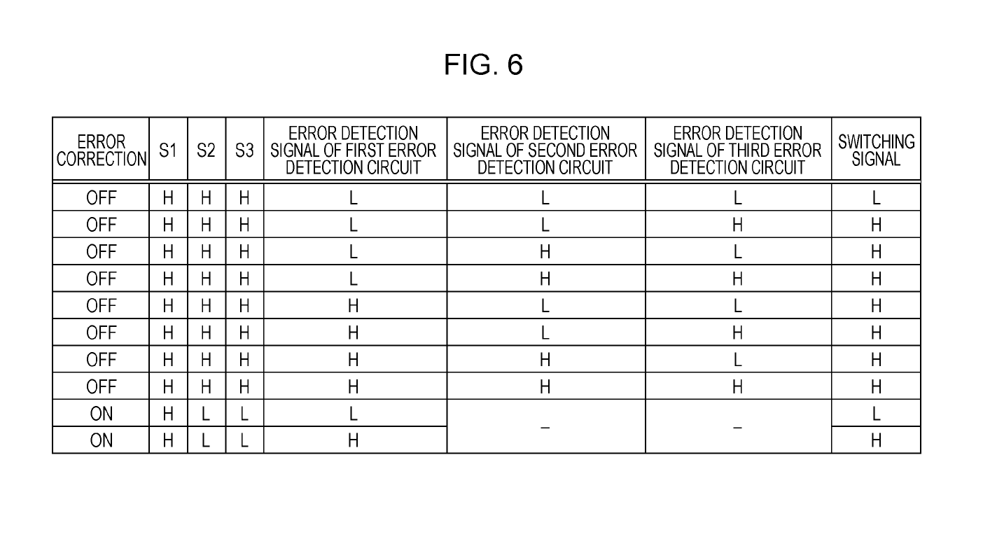

FIG. 6 is a logic table of selection signals S1 to S3, error detection signals, and a switching signal when advanced FEC is used. When advanced FEC is used, in the case where the error correction process is in an OFF state, the values of all the selection signals S1 to S3 are “H”. Thus, when any of the first error detection circuit 20, the second error detection circuit 21, and the third error detection circuit 22 detects an error, the value of the switching signal is “H”. In the case where the error correction process is in an ON state, the value of the selection signal S1 is “H” and the values of the selection signals S2 and S3 are “L”. Thus, the value of the switching signal is determined regardless of the error detection signals of the second error detection circuit 21 and the third error detection circuit 22. Hence, switching based on the error detection signals of the second error detection circuit 21 and the third error detection circuit 22 which are unnecessary when the error correction process performed by using advanced FEC is in an ON state is inhibited. As a result, the occurrence of unnecessary switching between transmission paths is reduced.

This embodiment reduces unnecessary switching between transmission paths that occurs on the basis of an error detection signal which is unnecessary due to improvement of the BER of a received signal when an error correction process is performed. As a result, instantaneous line disconnection caused by unnecessary switching between transmission paths is reduced, thereby reducing a frame loss caused by line disconnection.

Whether switching between transmission paths based on an error detection signal is permitted or not permitted is determined in accordance with the type of an error correction process performed, so that, when a plurality of error correction processes are selectively performed, an error detection signal may be disabled in accordance with the correction capability of each error correction process.

The switching signal control circuit 23 selects a switching signal for switching between transmission paths from among the error detection signals of the first error detection circuit 20, the second error detection circuit 21, and the third error detection circuit 22 which detect different errors. Thus, a switching signal is selected by the switching signal control circuit 23, thereby enabling a more simplified operation than that based on an automatic protection switching (APS) protocol in which signal paths are switched on the basis of different error detection signals.

The setting device 2 sets the selection signals S1 to S3 in association with an ON or OFF setting and a mode setting of an error correction process, thereby enabling suppression of an error in setting the selection signals S1 to S3.

### Second Embodiment

Next, another embodiment of the transmission apparatus 1 will be described. FIG. 7 illustrates a hardware configuration according to the second embodiment of the transmission apparatus 1. Components similar to those illustrated in FIG. 2 are denoted by the same reference numerals as used in FIG. 2, and description of the same functions is omitted. The transmission apparatus 1 includes a failure detection circuit 24 and an inverter 25.

The failure detection circuit 24 detects a failure of the receiving circuit 10 regardless of an ON or OFF state of the error correction process performed by the error correction circuit 14. The failure detection circuit 24 outputs a logic signal that indicates a detection result as a failure detection signal. The values “H” and “L” of the failure detection signal denote detection and no detection of the failure of the receiving circuit 10. The inverter 25 inverts the logic of the failure detection signal and inputs the failure detection signal to the switching signal control circuit 23. An operation performed by the failure detection circuit 24 will be described in detail below.

During a time period over which the failure detection circuit 24 detects a failure, that is, a time period over which an output value of the inverter 25 is “L”, the switching signal control circuit 23 inhibits switching between lines based on the error detection signals of the first error detection circuit 20, the second error detection circuit 21, and the third error detection circuit 22. That is, the switching signal control circuit 23 sets a value of a line switching signal to “L” regardless of the error detection signals of the first error detection circuit 20, the second error detection circuit 21, and the third error detection circuit 22.

Switching between lines is inhibited during the time period over which the failure of the receiving circuit 10 is detected, thereby reducing chattering caused by a temporary failure of the receiving circuit 10. Chattering is a phenomenon in which, when a temporary failure of the receiving circuit 10 occurs without there being any failures in a transmission path, switching back and forth between lines occurs due to increase in BERs of signals input to the first error detection circuit 20, the second error detection circuit 21, and the third error detection circuit 22. Chattering causes instantaneous line disconnection.

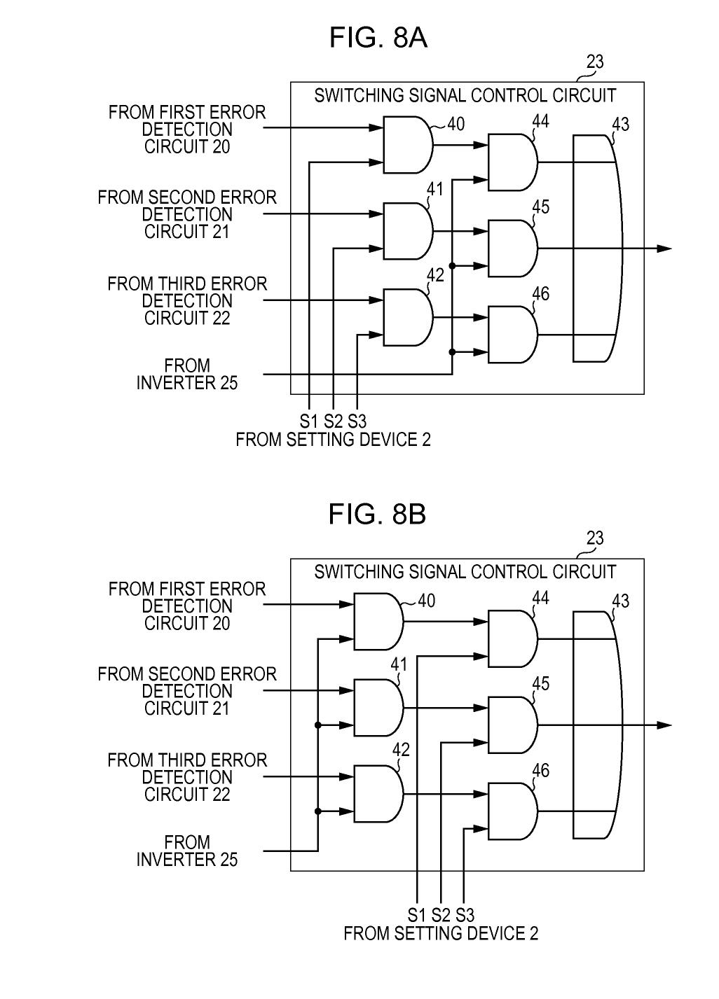

FIG. 8A illustrates an example of the configuration of the switching signal control circuit 23 according to the second embodiment. The switching signal control circuit 23 includes AND circuits 40, 41, 42, 44, 45, and 46, and the OR circuit 43. The AND circuit 40 outputs a logical product signal of the error detection signal of the first error detection circuit 20 and the selection signal 51. The AND circuit 41 outputs a logical product signal of the error detection signal of the second error detection circuit 21 and the selection signal S2. The AND circuit 42 outputs a logical product signal of the error detection signal of the third error detection circuit 22 and the selection signal S3.

The AND circuit 44 outputs a logical product signal of the output of the AND circuit 40 and the output of the inverter 25. The AND circuit 45 outputs a logical product signal of the output of the AND circuit 41 and the output of the inverter 25. The AND circuit 46 outputs a logical product signal of the output of the AND circuit 42 and the output of the inverter 25. The OR circuit 43 outputs a logical sum signal of the outputs of the AND circuits 40, 41, and 42 as the switching signal.

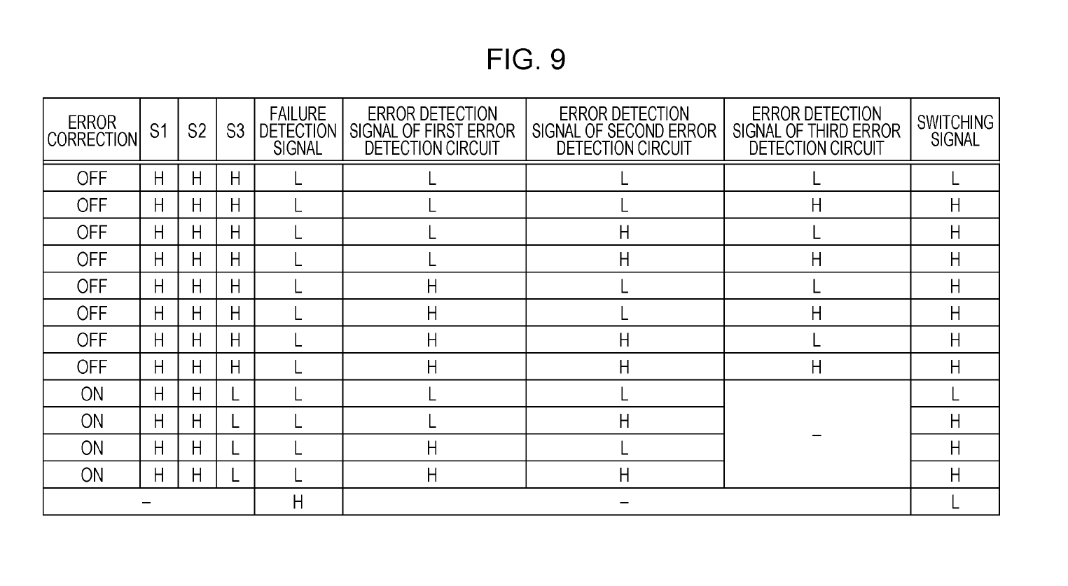

FIG. 9 is a logic table of selection signals S1 to S3, error detection signals, a failure detection signal, and a switching signal when RS (255, 239) correction is used. When the failure of the receiving circuit 10 is not detected, that is, when the value of the failure detection signal is “L”, the relationships between the selection signals S1 to S3 and the switching signal and between the error detection signals and the switching signal are similar to the relationships in FIG. 5. When the failure of the receiving circuit 10 is detected, that is, when the value of the failure detection signal is “H”, the value of the switching signal is “L” regardless of an ON or OFF state of the error correction process and the values of the error detection signals. Thus, when the failure of the receiving circuit 10 is detected, switching between lines based on the error detection signals of the first error detection circuit 20, the second error detection circuit 21, and the third error detection circuit 22 is inhibited.

Similarly, in the case where advanced FEC is used, when the failure of the receiving circuit 10 is not detected, the relationships between the selection signals S1 to S3 and the switching signal and between the error detection signals and the switching signal are similar to the relationships in FIG. 6. When the value of the failure detection signal is “H”, the value of the switching signal is “L” regardless of an ON or OFF state of the error correction process and the values of the error detection signals.

The switching signal control circuit 23 may have the configuration illustrated in FIG. 8B. The AND circuit 40 outputs a logical product signal of the error detection signal of the first error detection circuit 20 and the output of the inverter 25. The AND circuit 41 outputs a logical product signal of the error detection signal of the second error detection circuit 21 and the output of the inverter 25. The AND circuit 42 outputs a logical product signal of the error detection signal of the third error detection circuit 22 and the output of the inverter 25.

The AND circuit 44 outputs a logical product signal of the output of the AND circuit 40 and the selection signal S1. The AND circuit 45 outputs a logical product signal of the output of the AND circuit 41 and the selection signal S2. The AND circuit 46 outputs a logical product signal of the output of the AND circuit 42 and the selection signal S3. The OR circuit 43 outputs a logical sum signal of the outputs of the AND circuits 40, 41, and 42 as the switching signal.

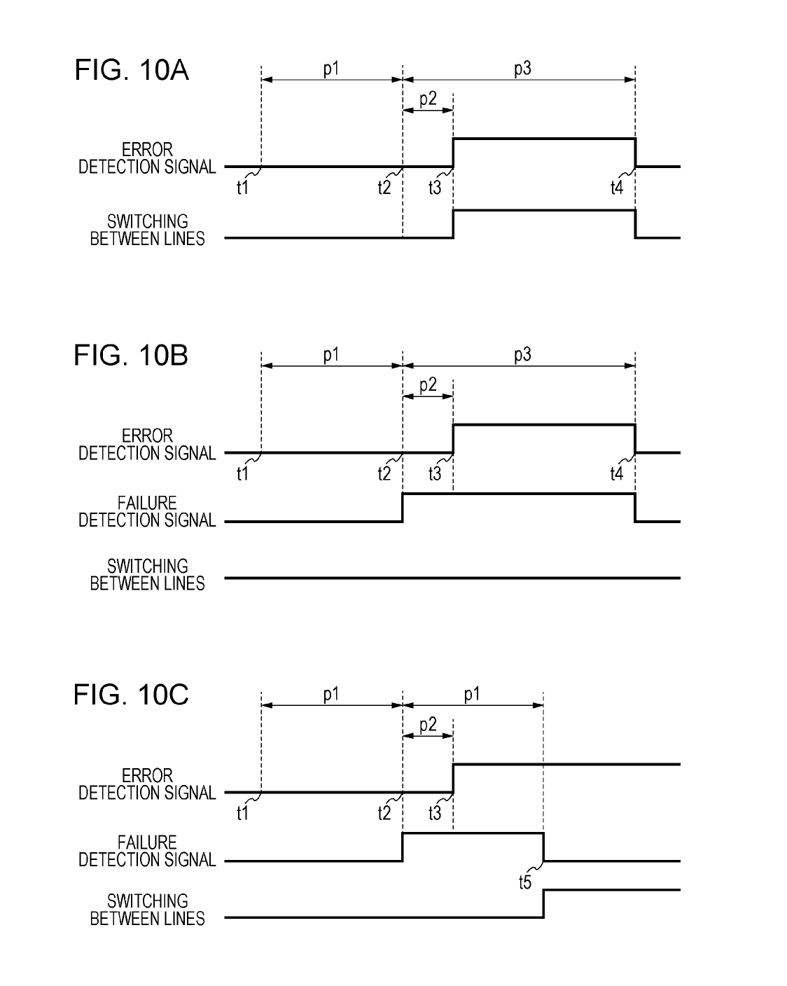

The operation performed by the failure detection circuit 24 will be described below with reference to FIGS. 10A to 10C, 11, and 12. For comparison purposes, FIG. 10A illustrates a switching operation of switching between lines performed when inhibition, based on a failure detection signal, of switching between lines is not performed. In the following description, in some cases, the first error detection circuit 20, the second error detection circuit 21, and the third error detection circuit 22 are collectively referred to as “the first error detection circuit 20 and the others”.

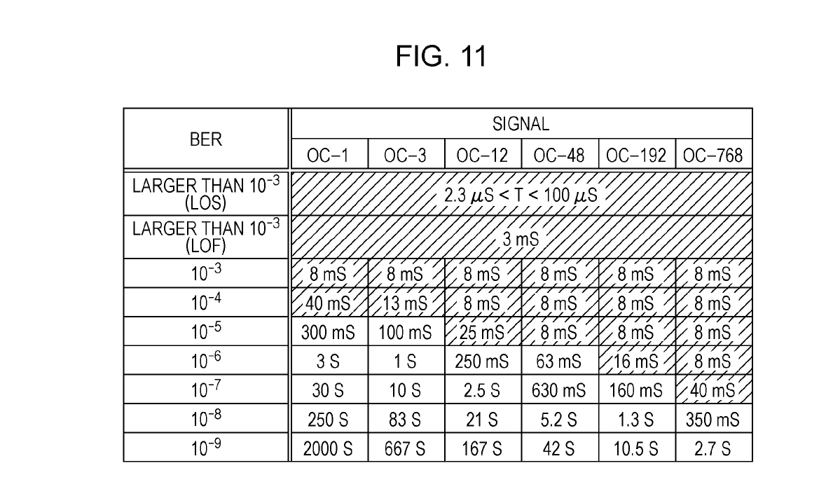

When a temporary failure of the receiving circuit 10 occurs at a time t1 and a BER increases, the first error detection circuit 20 and the others detect an error at a time t2 when an error detection time period p1 has elapsed, and a switching operation of switching between transmission paths starts. FIG. 11 is a table indicating an example of the error detection time period p1 defined by the GR-253-CORE. For example, the detection time period permitted for LOS detection is less than 100 μS and the detection time period permitted for LOF detection is 3 mS. If the assumption is made that a signal transmitted by the transmission apparatus 1 is an OC1 signal, for example, the detection time period permitted for SF error detection in which the BER is 10⁻³ is 8 mS and the detection time period permitted for SD error detection in which the BER is 10⁻⁶ is 3 S.

The first error detection circuit 20 and the others each output an error detection signal at a time t3 when a certain waiting time period p2 has elapsed from the time t2 which is a start time of switching. That is, the output value is changed from “L” to “H”. The switching circuit 16 performs reception switching on the basis of the error detection signal.

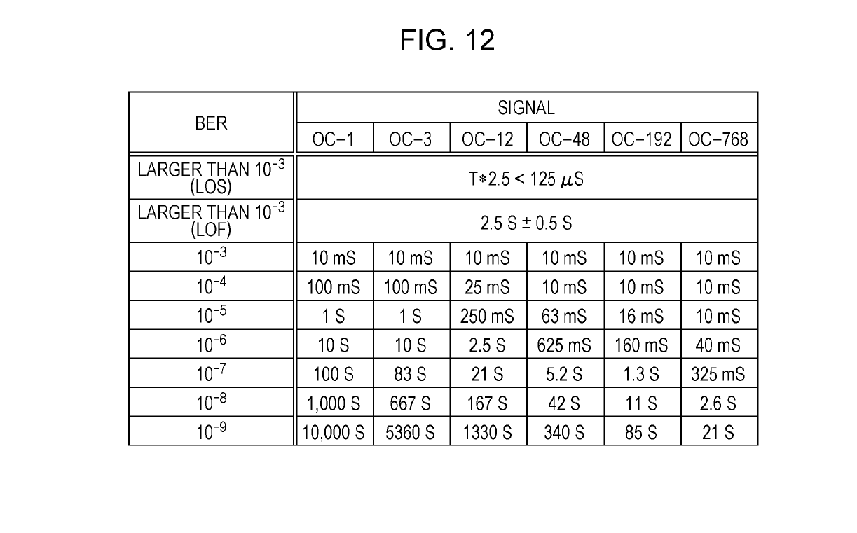

When the temporary failure of the receiving circuit 10 is restored after the time t2 which is the start time of switching, the first error detection circuit 20 and the others cancel output of the error detection signal at a time t4 when a cancellation time period p3 has elapsed. FIG. 12 is a table indicating an example of the cancellation time period p3 defined by the GR-253-CORE. The cancellation time period taken to cancel LOS detection is less than 125 μS and the cancellation time period taken to cancel LOF detection is 2.5 S plus or minus 0.5 S. If the assumption is made that a signal transmitted by the transmission apparatus 1 is an OC1 signal, for example, the cancellation time period taken to cancel SF error detection in which the BER is 10⁻³ is 10 mS and the cancellation time period taken to cancel SD error detection in which the BER is 10⁻⁶ is 10 S.

Switching back between transmission paths occurs due to cancellation of output of the error detection signal. Thus, when inhibition, based on the failure detection signal, of switching between lines is not performed, chattering caused by the temporary failure of the receiving circuit 10 occurs.

FIG. 10B illustrates a switching operation of switching between lines performed when a temporary failure of the receiving circuit 10 occurs in the case where switching between lines is inhibited in accordance with a failure detection signal. In this case, the failure detection circuit 24 outputs a failure detection signal at the time t2 which is the start time of switching. The failure detection circuit 24 continues outputting the failure detection signal until the temporary failure of the receiving circuit 10 is restored and the cancellation time period p3 elapses. This operation performed by the failure detection circuit 24 inhibits switching between transmission paths based on each error detection signal output from the first error detection circuit 20 and the others due to the occurrence of the temporary failure of the receiving circuit 10.

FIG. 10C illustrates a switching operation of switching between lines performed when an error due to a line failure occurs in the case where switching between lines is inhibited in accordance with a failure detection signal. In this case as well, the failure detection circuit 24 outputs a failure detection signal at the time t2 which is the start time of first switching. Note that, unlike the case of a temporary failure of the receiving circuit 10, an error due to a line failure continuously occurs. Thus, the first error detection circuit 20 and the others detect a second error at a time t5 when the error detection time period p1 has elapsed from the time t2.

When the first error detection circuit 20 and the others detect the second error, the failure detection circuit 24 stops outputting the failure detection signal. As a result, inhibition of switching between transmission paths based on each error detection signal of the first error detection circuit 20 and the others is cancelled and the switching circuit 16 performs reception switching.

Here, a switching time period for switching between transmission paths defined by Telcordia recommendation GR-1230-CORE, which is the specification standard of the transmission apparatus, is within 50 mS from the time t2 which is the start time of switching between transmission paths. Thus, detection of the second error is preferably performed within 50 mS from the time t2 which is the start time of switching between transmission paths, that is, it is preferable that the error detection time period p1 be 50 mS. The hatched section in FIG. 11 indicates the range within which an error is detected within 50 mS.

As illustrated in FIG. 11, when the BER is within the range of 10⁻⁵ to 10⁻⁹, in some cases, the error detection time period p1 is larger than 50 mS. However, the setting device 2 puts the error correction process performed by the error correction circuit 14 into an ON state and received signals having the BERs that are 10⁻⁵ to 10⁻⁹ thereby meet the signal quality standard defined by the GR-253-CORE, so that switching between transmission paths is unnecessary. Hence, the error correction process is put into an ON state and switching between transmission paths is not performed when the BERs of the received signals are 10⁻⁵ to 10⁻⁹, thereby allowing avoidance of the problem that the switching time period for switching between transmission paths is longer than the time period defined by the GR-1230-CORE.

This embodiment reduces the occurrence of unnecessary chattering caused by a temporary failure of the receiving circuit 10. As a result, instantaneous line disconnection caused by unnecessary switching between transmission paths is reduced, thereby reducing a frame loss caused by line disconnection.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A transmission apparatus comprising:
a switching signal generation circuit configured to generate a switching signal in accordance with an error of a received signal;
a switching circuit configured to perform reception switching in which a line through which the transmission apparatus receives a signal is switched from a working line to a protection line in accordance with the switching signal;
an error correction circuit configured to correct the error of the received signal; and
a switching signal control circuit configured to control input of the switching signal to the switching circuit in accordance with whether or not the error correction circuit corrects the error of the received signal.

2. The transmission apparatus according to claim 1, wherein
the switching signal generation circuit includes a first generation circuit that generates, as the switching signal, a first switching signal that indicates detection based on a first error rate of the received signal, and a second generation circuit that generates, as the switching signal, a second switching signal that indicates detection based on a second error rate of the received signal which is different from the first error rate, and
when the error correction circuit corrects the error of the received signal, the switching signal control circuit controls to input the first switching signal to the switching circuit and controls not to input the second switching signal to the switching circuit.

3. The transmission apparatus according to claim 2, wherein
the first error rate is an error rate of an error that the error correction circuit is impossible to correct, and
the second error rate is an error rate of an error that the error correction circuit is possible to correct.

4. The transmission apparatus according to claim 2, wherein
the switching signal control circuit inputs the first switching signal to the switching circuit regardless of whether or not the error correction circuit corrects the error of the received signal.

5. The transmission apparatus according to claim 1, wherein
the switching signal generation circuit includes a plurality of generation circuits that respectively generate, as the switching signal, detection signals that indicate detection based on a plurality of different error rates of the received signal, and
the switching signal control circuit selects, in accordance with a type of an error correction process performed by the error correction circuit, a switching signal to be input to the switching circuit from among switching signals generated by the plurality of generation circuits.

6. The transmission apparatus according to claim 5, wherein
the switching signal to be input to the switching circuit is a switching signal generated by the switching signal generation circuit that finds an error rate corresponding to an error that the error correction circuit is impossible to correct.

7. The transmission apparatus according to claim 1, further comprising:
a failure detection circuit configured to generate a failure detection signal that indicates a failure detected by a receiving circuit which receives the received signal,
wherein the switching signal control circuit inhibits input of the switching signal to the switching circuit in accordance with the failure detection signal.

8. The transmission apparatus according to claim 7, wherein,
when the switching signal generation circuit detects the error of the received signal after an error of the receiving circuit is detected, the failure detection circuit stops generating of the failure detection signal.

9. The transmission apparatus according to claim 8, wherein
the switching signal generation circuit generates, as the switching signal, a detection signal that indicates detection based on an error rate of the received signal whose error the error correction circuit is possible to correct,
a detection time period taken for the switching signal generation circuit to detect the error is longer than a switching time period permitted to perform reception switching in which the line through which the transmission apparatus receives the signal is switched from the working line to the protection line, and
when the error correction circuit corrects the error of the received signal, the switching signal control circuit inhibits input of the switching signal generated by the switching signal generation circuit to the switching circuit.

10. The transmission apparatus according to claim 8, wherein
the switching signal generation circuit generates, as the switching signal, a detection signal that indicates detection based on an error rate of the received signal whose error the error correction circuit is impossible to correct, and
the detection time period taken for the switching signal generation circuit to detect the error is shorter than a switching time period permitted to perform reception switching in which the line through which the transmission apparatus receives the signal is switched from the working line to the protection line.
